(19) United States
(12) Patent Application Publication
(10) Pub. No.: US 2023/0020805 A1
(43) Pub. Date: Jan. 19, 2023

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: JUNG-HUA CHEN, Hefei City (CN)

(73) Assignee: CHANGXIN MEMORY TECHNOLOGIES, INC., Hefei City (CN)

(21) Appl. No.: 17/947,630

(22) Filed: Sep. 19, 2022

Related U.S. Application Data
(63) Continuation of application No. PCT/CN2022/093996, filed on May 19, 2022.

(30) Foreign Application Priority Data
Jul. 20, 2021 (CN) 202110821360.8

(51) Int. Cl. H01L 27/108; H01L 29/78

(52) U.S. Cl. CPC H01L 27/10876; H01L 27/10885; H01L 27/10891; H01L 27/10823; H01L 29/7827

(57) ABSTRACT

A semiconductor structure includes a base in which a first doped region is provided and an active pillar group arranged in the first doped region. The active pillar group includes four active pillars arranged in an array. At least one of the active pillars is provided with a notch, which faces at least one of a row centerline or a column centerline of the active pillar group.

### CROSS-REFERENCE TO RELATED APPLICATIONS

This application is a continuation of International Application No. PCT/CN2022/093996, filed on May 19, 2022, which claims priority to Chinese Patent Application No. 202110821360.8, filed on Jul. 20, 2021. International Application No. PCT/CN2022/093996 and Chinese Patent Application No. 202110821360.8 are incorporated herein by reference in their entireties.

### BACKGROUND

Dynamic random access memory (DRAM) is a kind of semiconductor memory that writes and reads data randomly at a high speed, which is widely used in data storage equipment or devices.

Dynamic random access memory generally includes a plurality of active areas arranged in an array and transistors arranged in each active area. Each transistor includes an active pillar arranged vertically and a gate arranged around the active pillar. With the development of dynamic random access memory towards integration, distances between adjacent active pillars becomes smaller and smaller, which leads to leakage phenomenon between adjacent active pillars, thereby reducing the performance of the semiconductor structure.

### SUMMARY

The disclosure relates to the technical field of semiconductors, and in particular to a semiconductor structure and a manufacturing method thereof.

A first aspect of the embodiments of the disclosure provides a semiconductor structure, including a base and an active pillar group.

A first doped region is provided in the base.

The active pillar group is provided in the first doped region, and includes four active pillars arranged in an array. At least one of the active pillars is provided with a notch. The notch faces at least one of a row centerline or a column centerline of the active pillar group.

A second aspect of the embodiments of the disclosure provides a manufacturing method of a semiconductor structure, including the following operations.

A base is provided. A first doped region is provided in the base.

An active pillar group is formed in the first doped region. The active pillar group includes four active pillars arranged in an array. At least one of the active pillars is provided with a notch. The notch faces at least one of a row centerline or a column centerline of the active pillar group.

### BRIEF DESCRIPTION OF THE DRAWINGS

For the purpose of more clearly illustrating the technical solutions in the embodiments of this disclosure or the related art, the drawings needed to be used in the description of the embodiments or the related art are briefly described below. It is apparent that the drawings in the following description are some embodiments of the disclosure, from which other drawings may be obtained without creative effort by those of ordinary skill in the art.

FIG. 1 is a scheme diagram of a semiconductor structure provided by an embodiment of the disclosure;

FIG. 2 is a front view of FIG. 1;

FIG. 3 is a sectional view in the A-A direction of FIG. 2;

FIGS. 4 to 9 are schematic structural diagrams of the active pillars;

FIG. 10 is a process flow chart of a manufacturing method of a semiconductor structure provided by an embodiment of the disclosure;

FIG. 11 is a schematic structural diagram of a base in a manufacturing method of a semiconductor structure provided by an embodiment of the disclosure;

FIG. 12 is a perspective view of a mask in a manufacturing method of a semiconductor structure provided by an embodiment of the disclosure;

FIG. 13 is a top view of a mask in a manufacturing method of a semiconductor structure provided by an embodiment of the disclosure;

FIG. 14 is a schematic structural diagram of forming a pillar body in a manufacturing method of a semiconductor structure provided by an embodiment of the disclosure;

FIG. 15 is a schematic structural diagram of forming a first sub-dielectric layer in a manufacturing method of a semiconductor structure provided by an embodiment of the disclosure;

FIG. 16 is a schematic structural diagram of forming a second sub-dielectric layer in a manufacturing method of a semiconductor structure provided by an embodiment of the disclosure;

FIG. 17 is a schematic structural diagram of forming first mask strips in a manufacturing method of a semiconductor structure provided by an embodiment of the disclosure;

FIG. 18 is a schematic structural diagram of forming a first groove in a manufacturing method of a semiconductor structure provided by an embodiment of the disclosure;

FIG. 19 is a schematic structural diagram of forming first bit lines and second bit lines in a manufacturing method of a semiconductor structure provided by an embodiment of the disclosure;

FIG. 20 is a schematic structural diagram of removing first mask strips in a manufacturing method of a semiconductor structure provided by an embodiment of the disclosure;

FIG. 21 is a schematic structural diagram of forming a second dielectric layer in a manufacturing method of a semiconductor structure provided by an embodiment of the disclosure;

FIG. 22 is a schematic structural diagram of forming a third dielectric layer in a manufacturing method of a semiconductor structure provided by an embodiment of the disclosure;

FIG. 23 is a schematic structural diagram of forming second mask strips in a manufacturing method of a semiconductor structure provided by an embodiment of the disclosure;

FIG. 24 is a schematic structural diagram of forming first word lines and second word lines in a manufacturing method of a semiconductor structure provided by an embodiment of the disclosure;

FIG. 25 is a schematic structural diagram of removing the second mask strips in a manufacturing method of a semiconductor structure provided by an embodiment of the disclosure;

FIG. 26 is a schematic structural diagram of forming a fourth dielectric layer in a manufacturing method of a semiconductor structure provided by an embodiment of the disclosure;

FIG. 27 is a schematic structural diagram of forming mask blocks in a manufacturing method of a semiconductor structure provided by an embodiment of the disclosure;

FIG. 28 is a schematic structural diagram of forming filling holes in a manufacturing method of a semiconductor structure provided by the embodiment of the disclosure;

FIG. 29 is a schematic structural diagram of forming isolation structures in a manufacturing method of a semiconductor structure provided by embodiment of the disclosure;

FIG. 30 is a schematic structural diagram of forming a mask layer in a manufacturing method of a semiconductor structure provided by embodiment of the disclosure;

FIG. 31 is a perspective view of the mask layer provided by an embodiment of the disclosure;

FIG. 32 is a schematic structural diagram of forming an active pillar group in a manufacturing method of a semiconductor structure provided by an embodiment of the disclosure.

### DETAILED DESCRIPTION

As describe in the background, there is a problem of electric leakage between active pillars of semiconductor structures in related art. From research, the inventor found that the reason for this problem lies in short distances between adjacent active pillars, which leads to a short transmission path of electrons from one active pillar to another active pillar, thus causing the leakage phenomenon between adjacent active pillars.

In view of the above technical problem, in the embodiments of the disclosure, by providing a notch in at least one active pillar, a distance between a bottom wall of the notch recessed toward a center of the active pillar and another active pillar in a same row or column is increased is increased. Further, a migration path of electrons between the notch and the face opposite the notch is increased. The risk of electric leakage between the active pillar provided with the notch and another active pillar located in the same row or column is reduced, and thus the performance of the semiconductor structure is improved.

In order to make the above objects, features and advantages of the embodiments of the disclosure more readily understood, a clear and complete description of the technical solutions in the embodiments of the disclosure is given below in conjunction with the accompanying drawings in the embodiments of the disclosure. It is apparent that the embodiments described are only a part of the embodiments in this disclosure and not all of embodiments. Based on the embodiments in the disclosure, all other embodiments obtained by those of ordinary skill in the art without creative work are within the scope of protection of the disclosure.

The embodiments does not limit the semiconductor structure. The semiconductor structure is described below with dynamic random access memory (DRAM) as an example, but the embodiments are not limited to this. The semiconductor structure in this embodiments may also be other structures.

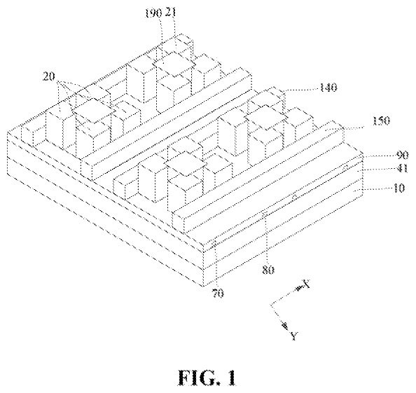

As shown in FIG. 1, a semiconductor structure provided by an embodiment of the disclosure may include a base 10 and an active pillar group 20. The base 10 may serve as a supporting component of the semiconductor structure, to support the active pillar group 20 provided on the base 10. The base 10 may be made of a semiconductor material which may be one or more of silicon, germanium, a silicon germanium compound, or a silicon carbon compound.

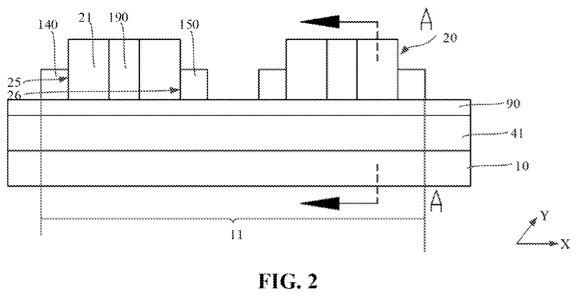

As shown in FIG. 2, a first doped region 11 may be provided in the base 10. The first doped region may serve as an array region for forming a semiconductor device, for example, for forming a transistor or a capacitor structure.

Exemplarily, the active pillar group 20 is provided in the first doped region 11. The active pillar group 20 includes four active pillars 21 in an array. For example, the four active pillars 21 may be arranged in a matrix, that is, the four active pillars 21 may be arranged in two rows and two columns.

At least one active pillar 21 is provided with a notch 22. The notch 22 faces at least one of a row centerline or column centerline of the active pillar group 20, that is, the notch faces an area enclosed by the four active pillars 21.

It is to be noted that in this embodiment, the row centerline can be understood as a centerline between a first row of active pillars and a second row of active pillars, and the column centerline can be understood as a centerline between a first column of active pillars and a second column of active pillars.

In the embodiment, by providing a notch on at least one active pillar, a distance between a bottom wall of the notch recessed toward a center of the active pillar and another active pillar in a same row or column is increased. Further, a migration path of electrons between the notch and the face opposite the notch is increased. The risk of electric leakage between the active pillar provided with the notch and another active pillar located in the same row or column is reduced, and thus the performance of the semiconductor structure is improved.

In the embodiment, at least one active pillar 21 is provided with a notch 22. It is to be understood that one active pillar 21 is provided with a notch 22, or two active pillars 21 are provided with notches 22, or three active pillars 21 are provided with notches 22, and further, four active pillars 21 are provided with notches.

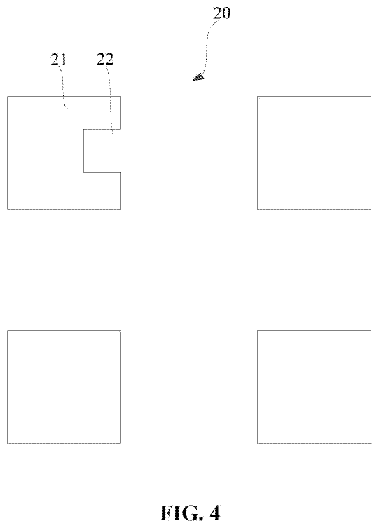

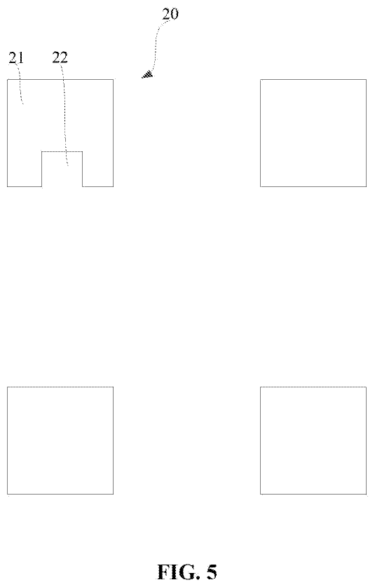

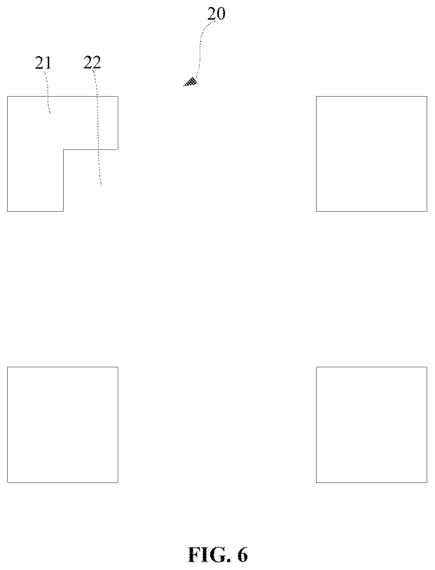

When one active pillar is provided with a notch, for example, as shown in FIG. 4, the notch 22 may be provided on a right side of the first active pillar 21 in the first row, and the notch 22 may face the column centerline. For example, the notch 22 faces the second active pillar 21 in the first row. For another example, as shown in FIG. 5, the notch 22 may also be provided on a lower side of the first active pillar 21 in the first row and may face the second active pillar 21 in the first column. Furthermore, as shown in FIG. 6, the notch 22 may also be provided at a corner of the first active pillar 21 in the first row toward a center of the area enclosed by the four active pillars 21, and the notch faces both the row centerline and the column centerline of the active pillar group.

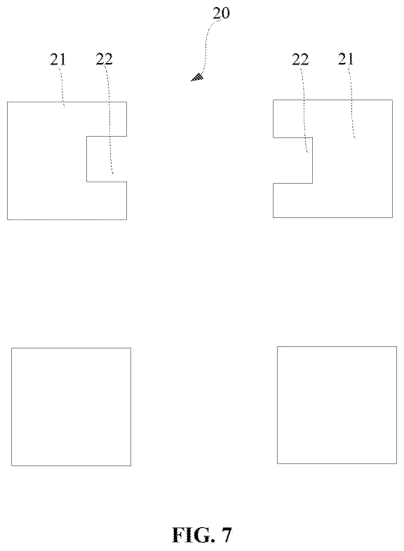

When two active pillars 21 are provided with notches 22, the two notches 22 may be provided in two adjacent active pillars 21 and at intervals. When provided in two adjacent active pillars 21, the two notches 22 may be disposed symmetrically. For example, as shown in FIG. 7, one notch 22 may be disposed in a first active pillar 21 in a first row, the other notch 22 is disposed in a second active pillar 21 in the first row, and the two notches 22 may be disposed symmetrically with respect to a column centerline.

When three active pillars are provided with notches, the notches are disposed in a manner similar to the above-mentioned one, and will not be listed again here in the embodiment.

When each of the four active pillars 21 is provided with a notch 22, the notches 22 are provided in the following manner.

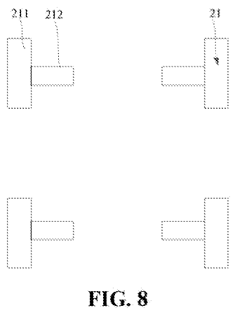

As shown in FIG. 8, each of the active pillars 21 includes a first pillar part 211 which may extend in a column direction and a second pillar part 212 connected to the first pillar part 211 which may extend in a row direction.

Among two active pillars 21 in a same row, a second pillar 212 is disposed on the side of the first pillar part 211 facing the other first pillar part 211. For example, as shown in FIG. 8, the second pillar 212 of the first active pillar 21 in the first row is disposed on the right side of the first pillar part 211, and the second pillar 212 of the second active pillar 21 in the first row is disposed on the left side of the first pillar part 211.

It is to be noted that in the embodiment, a second pillar 212 may be provided in the middle of the first pillar part 211, such that a cross-sectional shape of the active pillar 21 is T-shaped, or the second pillar 212 may be provided at either end of the first pillar part 211.

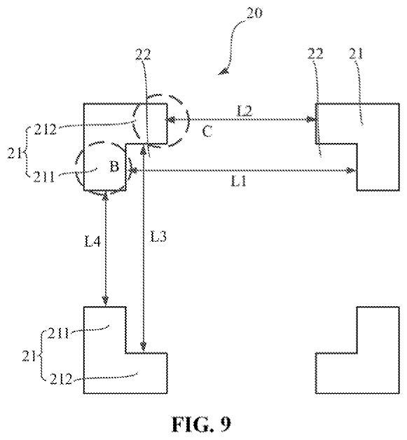

Exemplarily, as shown in FIG. 9, among two active pillars 21 in a same column, a second pillar 212 is disposed at the end of the first pillar part 211 away from the other first pillar part 211. Notches 22 provided in the two active pillars 21 located diagonally face each other, so that cross-sectional shapes of the active pillars 21 are L-shaped.

Referring to FIG. 9 again, the second pillar 212 of the first active pillar 21 in the first column is provided at an upper end of the first pillar part 211 of the active pillar 21, and the second pillar 212 of the second active pillar 21 in the first column is provided at a lower end of the first pillar part 211 of the active pillar 21. Moreover, the arrangements of the first active pillar 21 and the second active pillar 21 in the second column are the same as that of the first active pillar 21 and the second active pillar 21 in the first pillar part, respectively, and will not be described in detail here in the embodiment.

Taking an orientation shown in FIG. 9 as an example, when electrons in B region of the first active pillar 21 in the first row are to be transferred to the second active pillar in the first row, a length of the transmission path is L1. Compared with a transmission path L2 through which electrons in C region are transferred to the second active pillar in the first row, the transmission path of electrons in the B region is increased, thereby reducing leakage risk between two adjacent active pillars located in the same row, and thus improving the performance of the semiconductor structure.

In addition, when electrons in C region in the first active pillar 21 are to be transferred to the second active pillar in the first column, a length of the transmission path is L3. Compared with a transmission path L4 through which electrons in B region are transferred to the second active pillar in the first column, the transmission path of electrons located in C region is increased, thereby reducing leakage risk between two adjacent active pillars located in a same column, and thus improving the performance of the semiconductor structure.

In the embodiment, by providing a notch 22 on each of the active pillars 21, cross-sectional shapes of the active pillars 21 are L-shaped, and L-shaped openings each is provided toward a center of the active pillar group 20, thereby reducing the risk of electric leakage between adjacent active pillars in a same row and between adjacent active pillars in a same column, and thus improving the performance of the semiconductor structure.

Referring to FIG. 1 again, the number of the active pillar groups 20 may be multiple, and the multiple active pillar groups 20 are arranged in an array in the base 10. For example, the multiple active pillar groups 20 may be arranged in a rectangular array in the base.

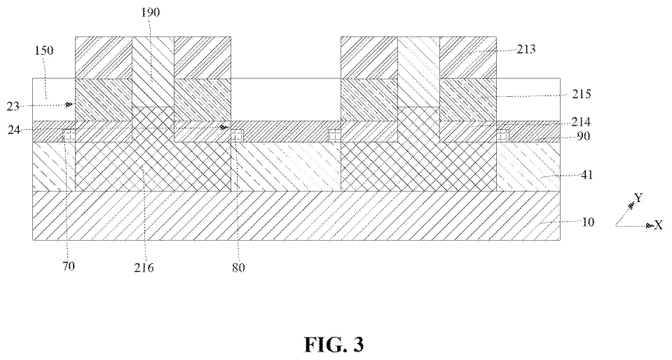

In some embodiments, as shown in FIG. 3, in a direction perpendicular to the base 10, each of the active pillars 21 includes a channel region 215, and a source region 213 and a drain region 214 that respectively provided at either end of the channel region. For example, each of the active pillar 21 includes a drain region 214, a channel region 215 and a source region 213 that are sequentially stacked from bottom to top in the direction perpendicular to the base 10.

Each of the active pillar groups 20 further includes a channel connecting region 216 through which drain regions 214 of each active pillar group 20 are connected to each other. The channel regions 215 are connected to the channel connecting region 216, and the channel connecting region 216 is connected to the base 10.

In the embodiment, the drain regions 214 of the active pillars 21 are connected by a channel connecting region 216, which is configured to connect VBB voltage, so that the voltages of the drain regions 214 of the active pillars 21 are the same and equal to the VBB voltage, thereby ensuring the stability of a critical voltage of the semiconductor structure. Thus, floating body effect can be reduced.

In some embodiments, as shown in FIG. 3, the semiconductor structure further includes multiple first bit lines 70 and multiple second bit lines 80. The multiple first bit lines 70 and the multiple second bit lines 80 are alternately arranged in a first direction, and the first bit lines 70 and the second bit lines 80 extend in a second direction. The first direction intersects the second direction.

The first direction is the X direction in FIG. 1, and the second direction is the Y direction in FIG. 2.

In the first direction, each of the active pillar groups 20 includes a first surface 23 and a second surface 24 disposed oppositely. A first bit line 70 is disposed on the first surface 23 and connects drain regions 214 of the active pillars 21 located in a same column corresponding to the first surface 23. A second bit line 80 is disposed on the second surface 24 and connects drain regions 214 of the active pillars 21 located in a same column corresponding to the second surface 24.

In the embodiment, the first bit line and the second bit line are arranged on front and back sides of the active pillar group to allow inner sides of the active pillars in the active pillar group to be connected for connecting VBB voltage, so that floating body effect can be reduced.

In some embodiments, as shown in FIG. 2, the semiconductor structure further includes multiple first word lines 140 and multiple second word lines 150 alternately arranged in the second direction. The first word lines 140 and the second word lines 150 extend in the first direction.

In the second direction, each of the active pillar groups 20 includes a third surface 25 and a fourth surface 26 disposed oppositely. A first word line 140 is disposed on the third surface 25 and connects the channel regions 215 of the active pillars 21 located in a same row corresponding to the third surface 25. A second word line 150 is disposed on the fourth surface 26 and connects the channel regions 215 of the active pillars 21 located in a same row corresponding to the fourth surface 26.

In the embodiment, the first bit line and the second bit line are arranged on the left and right sides of the active pillar group to allow the inner sides of the active pillars in the active pillar group to be connected for connecting VBB voltage, so that floating body effect can be reduced.

In some embodiments, the semiconductor structure further includes multiple isolation structures 190. Each of the isolation structures is disposed within an area enclosed by multiple active pillars 21 in each active pillar group 20, and the bottom surface of an isolation structure 190 is higher than the top surface of the drain region 214. In addition, the bottom surface of the isolation structure 190 is lower than the top surfaces of the channel regions 215.

In the embodiment, floating body effect can be reduced by connecting the active pillars in a same active pillar group together through an isolation structure.

In some embodiments, a capacitor (not shown in the figure) is provided on each active pillar 21. A lower electrode layer of the capacitor is connected to the source region of the active pillar.

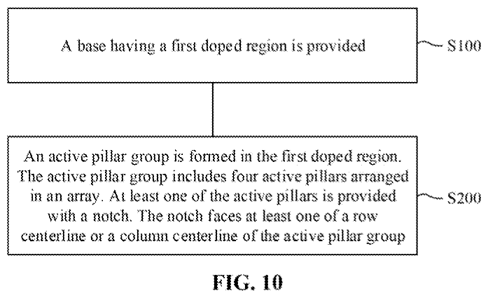

As shown in FIG. 10, a manufacturing method of a semiconductor structure provided by the embodiments of the disclosure includes the following operations.

In S100, a base is provided. A first doped region is provided in the base.

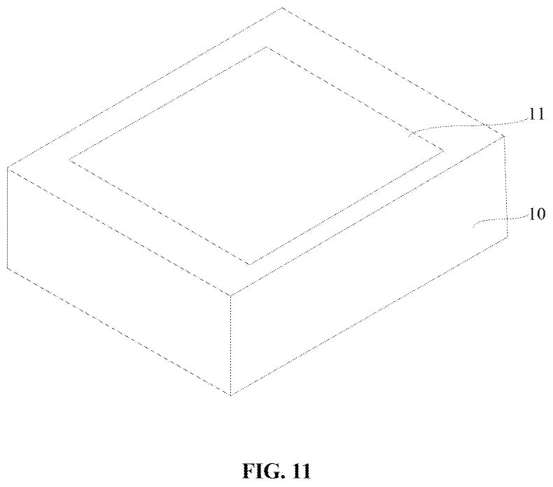

Exemplarily, as shown in FIG. 11, the base 10 serves as a supporting component of dynamic random access memory, to support other components provided thereon. A first doped Region 11 is provided in the base 10. The first doped Region 11 may include an array region for forming a semiconductor device, for example, for forming a transistor or a capacitor structure.

The operation of forming the first doped region 11 can be performed in the following manner.

First, a substrate is provided, in which a material of the substrate may include silicon oxide.

Secondly, a first protective layer and a mask layer with a mask pattern are formed on the substrate.

For example, the first protective layer may be formed on the substrate by a deposition process. Then a photoresist layer of a certain thickness is formed on the first protective layer by a coating process, and the photoresist layer may further be patterned by exposure, development or etching to form the mask layer having the mask pattern. The mask pattern may include mask openings.

Then, ion doping is performed on the substrate by an ion implantation technique. For example, doping ions may be implanted into the mask openings by the ion implantation technique, so that the doping ions enter the substrate exposed in the mask openings to form the first doped region 11. The substrate having the first doped region 11 constitutes the base 10.

It is to be noted that in the embodiment, the doping ions in the first doped region may be P-type ions or N-type ions.

In S200, an active pillar group is formed in the first doped region. The active pillar group includes four active pillars arranged in an array. At least one active pillar is provided with a notch. The notch faces at least one of a row centerline or column centerline of the active pillar group.

Exemplarily, in S210, a mask is provided. The mask includes a rectangular first mask region and multiple second mask regions. Four second mask regions are respectively arranged at corners of the first mask region, and each second mask region wraps a corner of the first mask region.

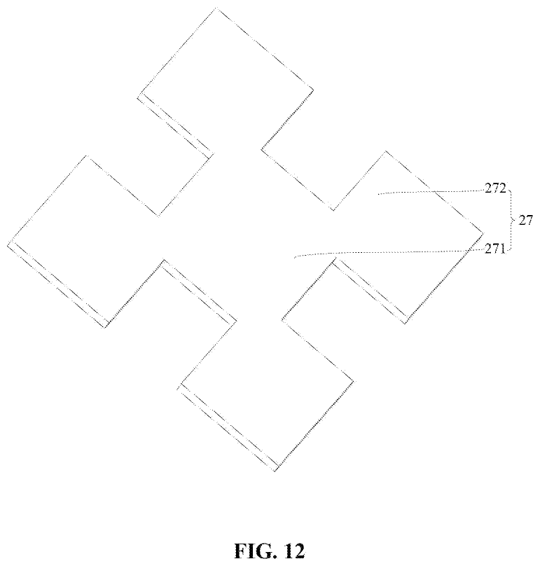

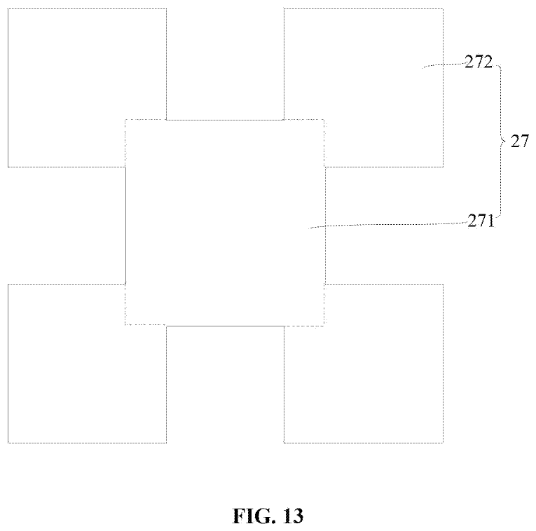

As shown in FIGS. 12 and 13, taking a direction parallel to the base 10 as a cross section, a cross-sectional shape of the first mask region 271 is rectangular cross-sectional shapes of the second mask regions 272 are L-shaped, and openings of the L-shaped second mask regions 272 face a center of the first mask region 271.

In S220, the base that is not shielded by the mask is etched by applying the mask to form pillar bodies in the first doped region. Each of the pillar bodies includes a first pillar body and four second pillar bodies. Taking a plane parallel to the base as a cross section, a cross-sectional shape of the first pillar body is rectangular, the four second pillar bodies are respectively arranged at the corners of the first pillar body, and each of the second pillar bodies wraps a corner of the first pillar body.

In the embodiment, the mask 27 may be a positive photoresist layer. When the mask 27 is exposed or developed, the base 10 not shielded by the mask plate 27 is etched away. The retained base 10 constitutes the pillar bodies 30, and the pillar bodies 30 are located in the first doped region.

A pillar body 30 includes a first pillar body 31 and four second pillar bodies 32. Taking a plane parallel to the base 10 as a cross section, a cross-sectional shape of the first pillar body 31 is rectangular, the four second pillar bodies 32 are respectively arranged at the corners of the first pillar body 31, and each of the second pillar bodies 32 wraps a corner of the first pillar body 31.

It is to be noted that in the embodiment, the number of the mask 27 may be one or multiple. When the number of the mask 27 is one, a pillar body 30 is formed in the base 10 accordingly. When the number of the masks 27 is multiple, multiple pillar bodies 30 may be formed in the base 10 with the multiple masks 27 as a mask. The multiple pillar bodies 30 are arranged in an array in the base 10.

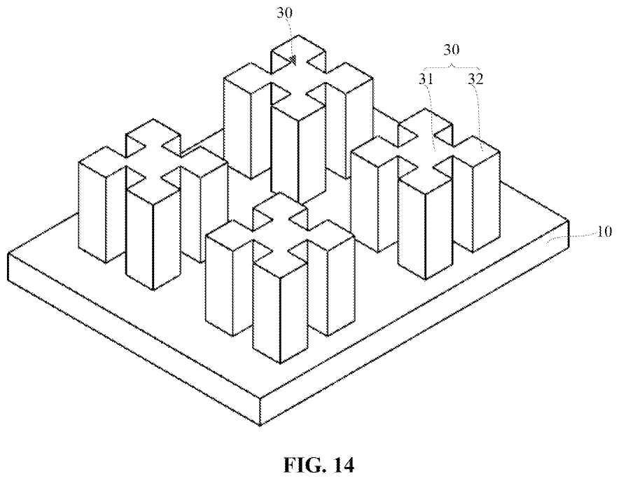

For example as shown in FIG. 14, the number of the pillar bodies 30 is four, and the four pillar bodies 30 are arranged on the base 10 in two rows and two columns.

In some embodiments, after the operation of applying the mask and before the operation of removing a partial thickness of the first pillar body, the manufacturing method of a semiconductor structure further includes the following operations.

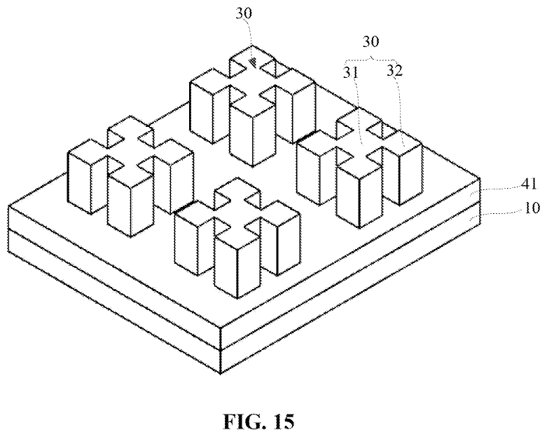

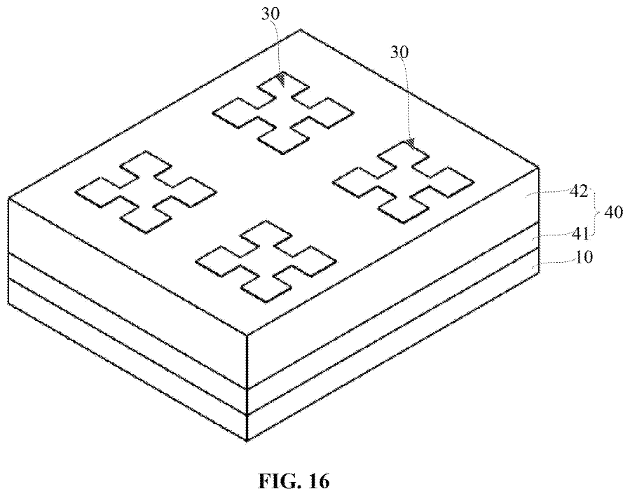

As shown in FIGS. 15 and 16, a first dielectric layer 40 covering the pillar bodies 30 is formed on the base 10. A top surface of the first dielectric layer 40 is flush with the top surfaces of the pillar bodies 30.

Exemplarily, the first dielectric layer 40 may be formed on the base 10 by a deposition process, in which the first dielectric layer wraps the side surfaces of the pillar bodies 30.

The first dielectric layer 40 may be formed by one deposition process, or by two deposition processes. For example, as shown in FIG. 16, the first dielectric layer 40 may include a first sub-dielectric layer 41 and a second sub-dielectric layer 42. Exemplarily, it is possible that the first sub-dielectric layer 41 is formed on the base 10 by a deposition process, and then the second sub-dielectric layer 42 is formed on the first sub-dielectric layer 41 by a deposition process. A top surface of the second sub-dielectric layer 42 is flush with the top surfaces of the pillar bodies 30.

Materials of the first sub-dielectric layer 41 and the second sub-dielectric layer 42 may be the same or different. For example, an etching rate of the first sub-dielectric layer 41 is smaller than an etching rate of the second sub-dielectric layer 42, so that the first sub-dielectric layer 41 can be used as an etching stop layer, and a thickness of the etched first dielectric layer 40 can be accurately controlled when a partial thickness of the first dielectric layer 40 is etched later.

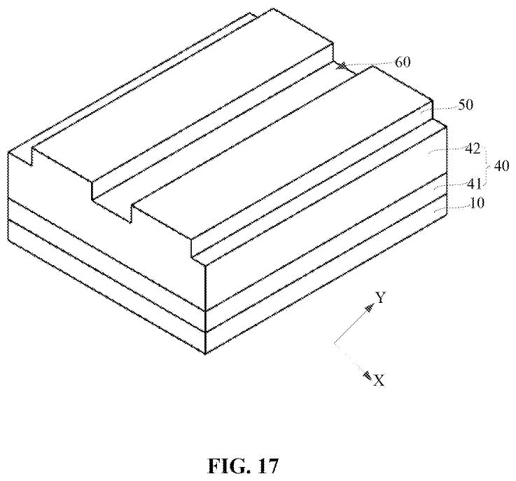

As shown in FIG. 17, after the first dielectric layer 40 is formed, multiple first mask strips 50 extending in the second direction are formed on the first dielectric layer 40. The multiple first mask strips 50 are arranged at intervals in the first direction, and a first opening 60 is formed between two adjacent first mask strips 50. The first opening 60 exposes the first dielectric layer 40 between two adjacent columns of pillar bodies 30.

Exemplarily, it is possible that a photoresist layer of a certain thickness is formed on the first dielectric layer 40 by a coating process. Then the photoresist layer is patterned to form multiple first mask strips 50 and an opening between adjacent first mask strips 50 in the photoresist layer.

In the embodiment, the first direction may be the X direction shown in FIG. 17, that is, the row direction. The second direction may be the Y direction shown in FIG. 17, that is, the column direction.

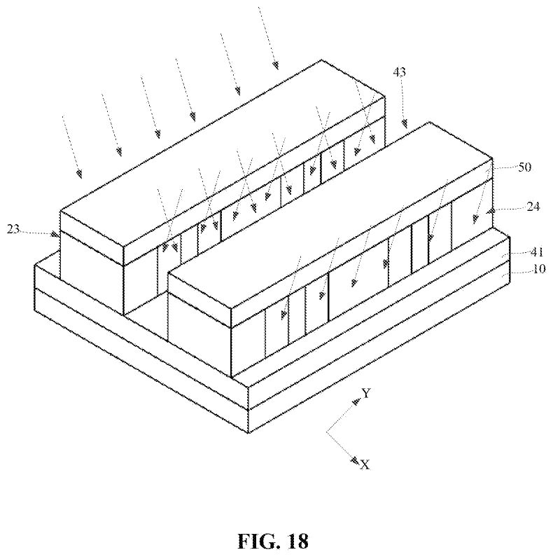

As shown in FIG. 18, a partial thickness of the first dielectric layer 40 exposed in the first opening 60 is removed to form a first groove 43, which exposes a first surface 23 and a second surface 24 of an active pillar group 20 that are arranged oppositely in the first direction.

Exemplarily, the second sub-dielectric layer 42 exposed in the first opening 60 may be removed by using an etching liquid or an etching gas, to form a first groove 43 in the first dielectric layer 40.

In the first direction, an active pillar group 20 has a first surface 23 and a second surface 24. A first groove 43 may expose a first surface 23 of one of two adjacent active pillar groups 20 and a second surface 24 of the other active pillar group 20.

Referring to FIG. 18 again, after the first groove 43 is formed, ion implantation may be performed on the first surface 23 and the second surface 24 using an ion implantation technique, so that a second doped region is formed in the second pillar body. A type of the doping ions in the second doped region is different from that of the first doped region 11, and the second doped region is configured to form a drain region.

It is to be understood that, doping ions in the second doped region are different from those in the first doped region 11. For example, the doping ions in the first doped region 11 are P-type ions, and accordingly, the doping ions in the second doped region are N-type ions. For another example, the doping ions in the first doped region 11 are N-type ions, and accordingly, the doping ions in the second doped region are P-type ions.

In some embodiments, after the operation of removing a partial thickness of the first dielectric layer exposed in the first opening and before the operation of performing ion implantation on exposed opposite surfaces of adjacent second pillar bodies in a first direction, the manufacturing method includes the following operations.

A second protective layer is formed on the second pillar bodies 32 exposed in a first groove 43. The second protective layer is configured to protect the second pillar bodies so as to prevent the first surfaces 23 and the second surfaces 24 from being damaged. A material of the second protective layer may include silicon dioxide, silicon nitride and silicon oxynitride.

After the second doped regions are formed, the second protective layer is removed.

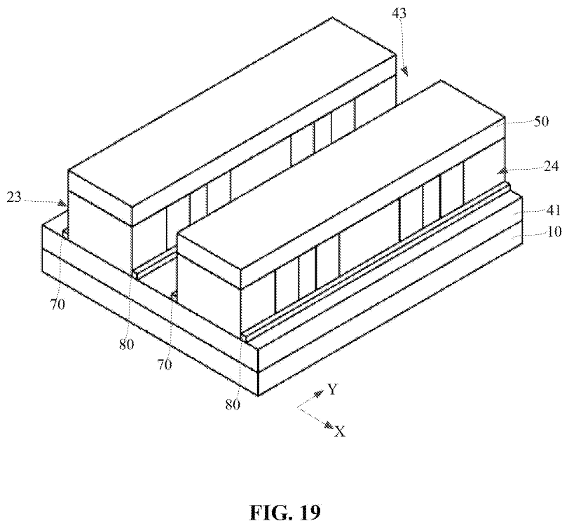

Then, as shown in FIG. 19, a first bit line 70 and a second bit line 80 are formed in a first groove 43. The first bit line 70 and the second bit line 80 are both extend in the second direction. The first bit line 70 connects the drain regions of the pillar bodies 30 corresponding to the first surfaces 23 exposed in the first groove 43, and the second bit line 80 connects the drain regions of the pillar bodies 30 corresponding to the second surfaces 24 exposed in the first groove 43.

Exemplarily, a bit line conductive layer may be deposited in a first groove 43. The bit line conductive layer fills up the first groove 43, and the top surface of the bit line conductive layer is flush with the top surface of the pillar bodies. Then, the bit line conductive layer is etched back, and the retained bit line conductive layer constitutes a first bit line 70 and a second bit line 80. A material of the first bit line 70 and the second bit line 80 may include tungsten.

In the embodiment, a first bit line and a second bit line are provided on a left side and a right side of a pillar body respectively. Compared with the technical solution in which a bit line is provided at a bottom of a pillar body in the related art, the problem of an unstable critical voltage of a component caused by floating body effect can be mitigated.

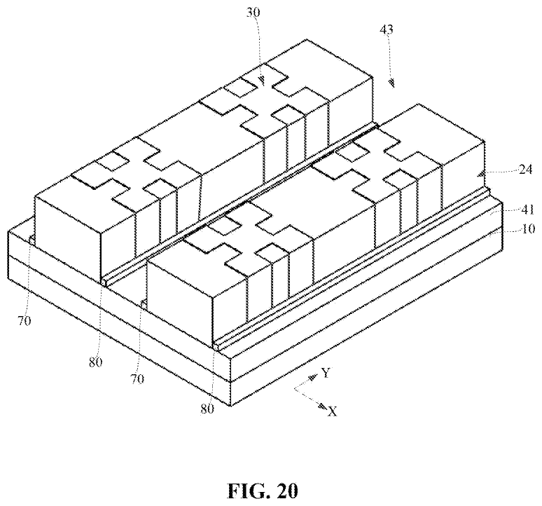

After the first bit lines and the second bit lines are formed, the first mask strips are removed by using a cleaning solution, as shown in FIG. 20.

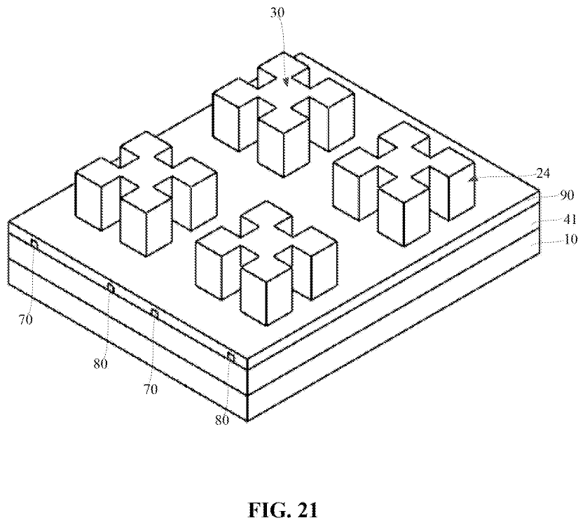

After the first mask strips are removed, first, as shown in FIG. 21, a second dielectric layer 90 is formed in the first grooves by a deposition process. A top surface of the second dielectric layer 90 is lower than the top surfaces of the pillar bodies 30. A material of the second dielectric layer 90 may include silicon oxide.

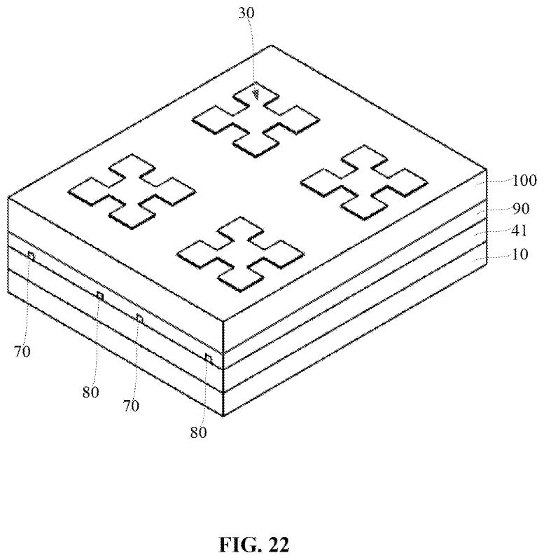

Then, as shown in FIG. 22, a third dielectric layer 100 is formed on the second dielectric layer 9) by a deposition process. A top surface of the third dielectric layer 100 is flush with the top surfaces of the pillar bodies 30, and a material of the third dielectric layer 100 may be the same as or different from that of the second dielectric layer 90.

In the embodiment, the second dielectric layer and the third dielectric layer, which are independent of each other, are formed in the first groove, so as to facilitate the subsequent back-etching of the third dielectric layer.

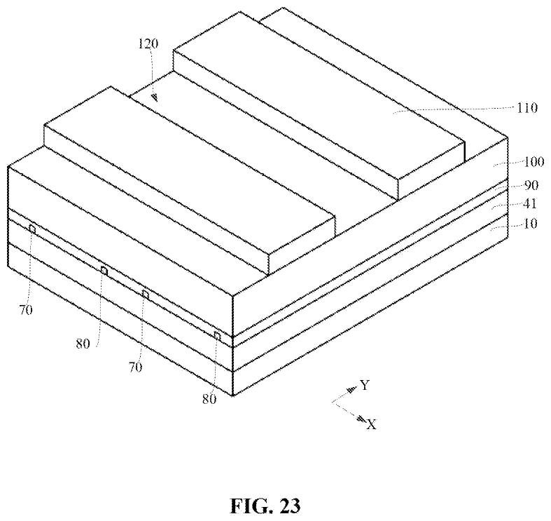

As shown in FIG. 23, after the third dielectric layer 100 is formed, second mask strips 110 extending in the first direction may be formed on the third dielectric layer 100. The multiple second mask strips 110 are arranged at intervals in the second direction, and a second opening 120 is formed between two adjacent second mask strips 110. The second opening 120 exposes the third dielectric layer 100 between two adjacent rows of pillar bodies.

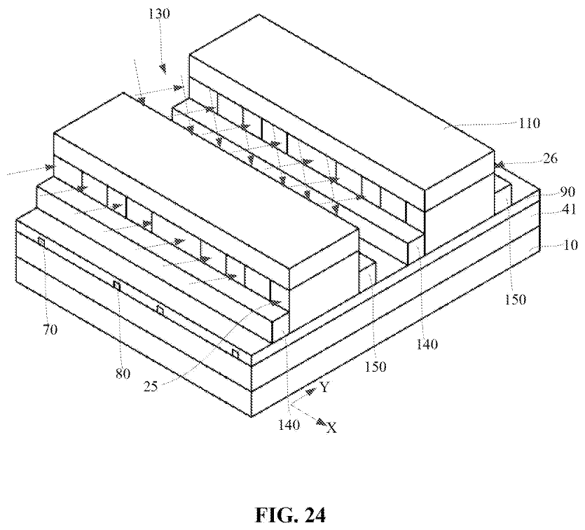

As shown in FIG. 24, the third dielectric layer 100 exposed in the second openings 120 is removed with an etching liquid or an etching gas, to form second grooves 130 that expose a third surface 25 and a fourth surface 26 of an active pillar group that are arranged oppositely in the second direction.

Referring to FIG. 24 again, ion implantation is performed on the third surface 25 and the fourth surface 26 using an ion implantation technique to form third doped regions in the second pillar bodies 32. A type of doping ions in the third doped regions is different from the type of doping ions in the second doped regions and identical to the type of doping ions in the first doped region. The third doped regions are configured to form channel regions.

It is to be noted that, when the doping ions in the first doped region are P-type ions, the doping ions in the third doped regions are P-type ions. That is, the doping ions in the channel regions are P-type ions. In the embodiment, the second doped regions already formed in the pillar bodies are protected by the second dielectric layer 90, to prevent the doping ions for forming the third doped regions from penetrating into the second doped regions, thereby improving the performance of the semiconductor structure.

After the operation of removing the third dielectric layer exposed in the second openings to form the second grooves, and before the operation of performing ion implantation on the exposed opposite surfaces of the second pillar body adjacent in the second direction, the manufacturing method of a semiconductor structure further includes the following operations.

A third protective layer is formed on the second pillar bodies 32 exposed in the second grooves 130. The third protective layer is configured to protect the second pillar bodies 32 so as to prevent the third surfaces and the fourth surfaces from being damaged. A material of the third protective layer may include silicon dioxide, silicon nitride and silicon oxynitride.

After the third doped regions are formed, the third protective layer is removed.

Then, referring to FIG. 24 again, a first word line 140 and a second word line 150 are formed in the second grooves 130. Both the first word line 140 and the second word line 150 extend in the first direction. The first word line 140 connects the channel regions of the pillar bodies 30 corresponding to the third surfaces 25 exposed in the second groove 130, and the second word line 150 connects the channel regions of the pillar bodies 30 corresponding to the fourth surfaces 26 exposed in the second groove 130.

Exemplarily, a word line conductive layer may be formed in the second grooves 130. The word line conductive layer fills up the second groove 130, and a top surface of the word line conductive layer is flush with the top surfaces of the pillar bodies. Then, the word line conductive layer is etched back to form the first word line 140 and the second word line 150 arranged at intervals in the second groove 130. A material of the first word line 140 and the second word line 150 include titanium nitride and polysilicon.

In the embodiment, by arranging the first word line and the second word line on either side of a pillar body respectively, a parasitic capacitance between word lines can be reduced, and thereby the interference between word lines can be reduced.

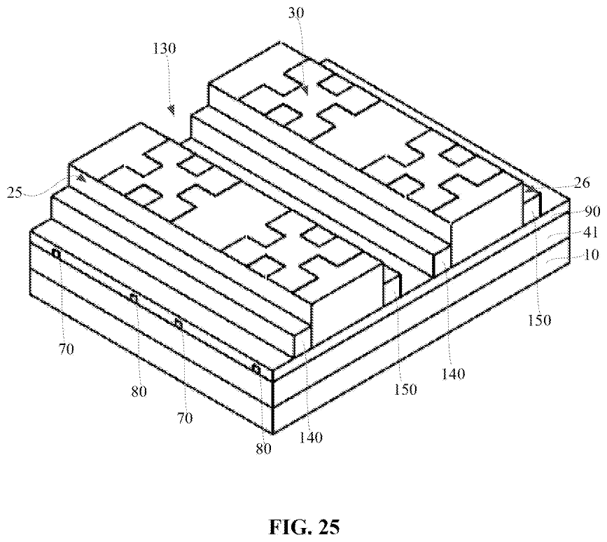

As shown in FIG. 25, after the first word lines 140 and the second word lines 150 are formed, the second mask strips 110 are removed by using a cleaning solution.

It is to be noted that after the operation of performing ion implantation on the third surfaces and the fourth surfaces, and before the operation of forming the first word lines and the second word lines in the second grooves, the manufacturing method of a semiconductor structure further includes the following operations.

A gate oxide layer is formed on a channel region using an atomic layer deposition process. A material of the gate oxide layer may have a high dielectric constant, for example, the material of the gate oxide layer includes alumina.

In S300, a partial thickness of a first pillar body is removed, and each second pillar body retained constitutes an intermediate active pillar.

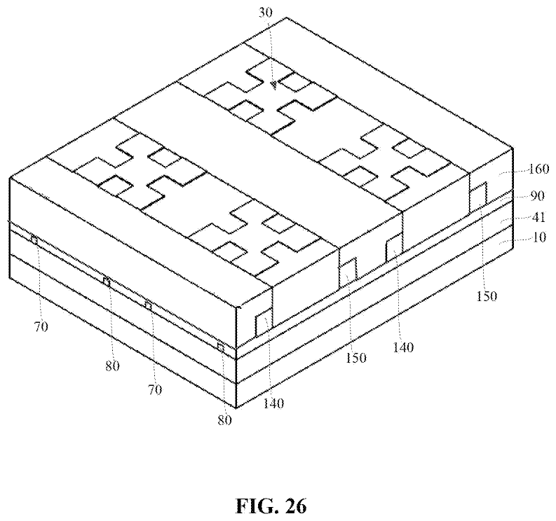

Exemplarily, as shown in FIG. 26, fourth dielectric layers 160 are deposited in the second grooves 130. The top surfaces of the fourth dielectric layers are flush with the top surfaces of the pillar bodies 30.

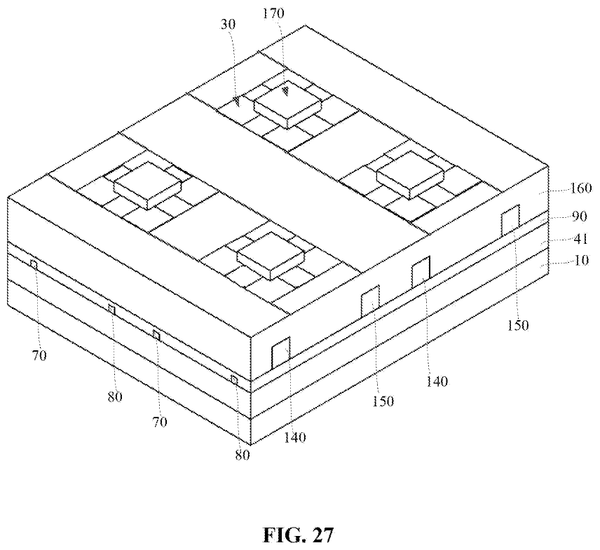

As shown in FIG. 27, multiple mask blocks 170 are formed on the fourth dielectric layer 160. A projection of each mask block 170 on the fourth dielectric layer 160 covers each first pillar body 31, and the mask blocks 170 may be negative photoresist.

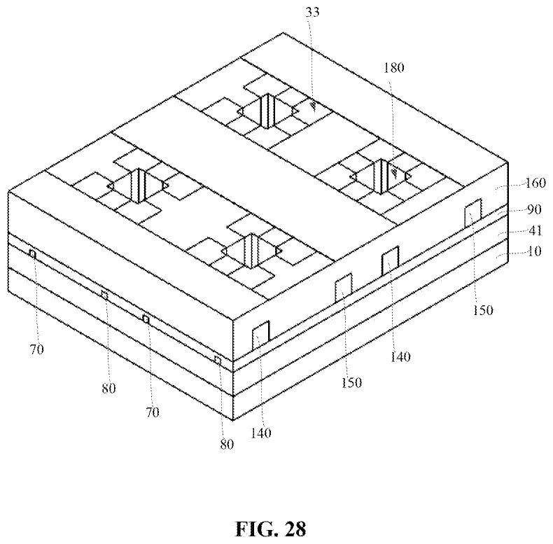

As shown in FIG. 28, after the mask blocks 170 are formed, a partial thickness of a first pillar body 31 shielded by a mask block 170 is removed, to form a filling hole 180. A bottom of the filling hole 180 is an upper surface of the first sub-dielectric layer 41, and each second pillar body 32 retained constitutes an intermediate pillar body 33.

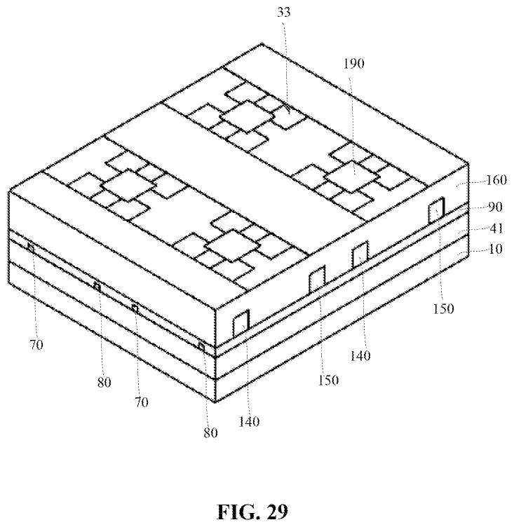

As shown in FIG. 29, isolation structures 190 are formed in the filling holes 180 by a deposition process. The top surfaces of the isolation structures 190 are flush with top surfaces of the intermediate pillars 33.

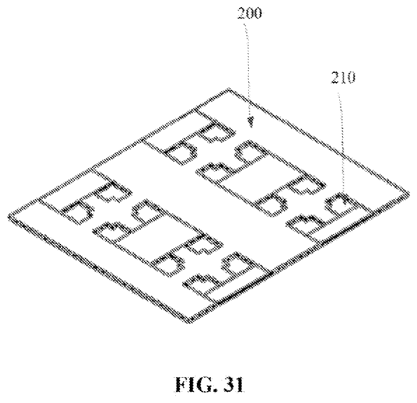

As shown in FIGS. 29 and 31, after the isolation structures 190 are formed, a mask layer 200 is formed on the fourth dielectric layer 160. The mask layer 200 has multiple mask openings 210, each of which has an L shape and exposes an intermediate pillar body 33.

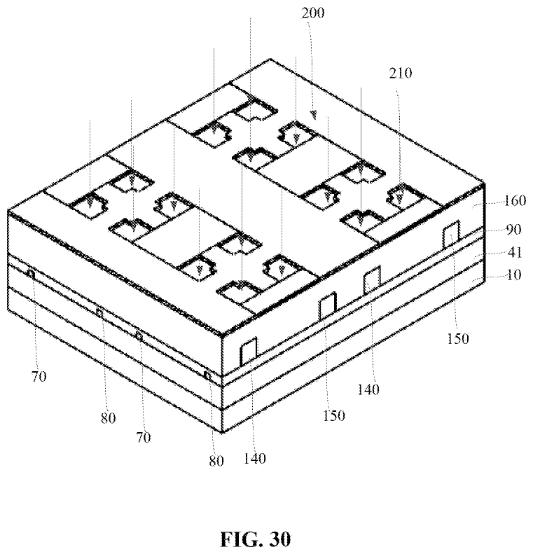

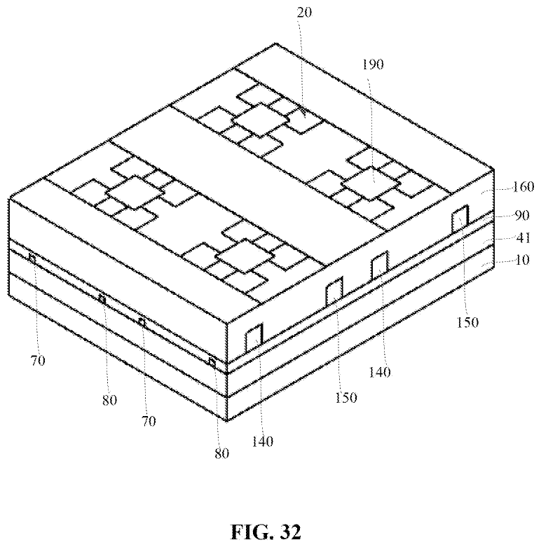

Then, as shown in FIG. 30, ion implantation is performed on a top surface of the intermediate pillar body 33 by an ion implantation process, to form a source region on the top surface of the intermediate pillar body 33. The intermediate pillar body with the source region formed thereon is regarded to be an active pillar 21. Four active pillars 21 constitute one active pillar group 20, and the structure is shown in FIG. 32.

In the active pillar group manufactured in the above way in the embodiment, a notch is provided on each active pillar, so that a cross-sectional shape of the active pillar is L-shaped. The L-shaped openings are all arranged towards a center of the active pillar group, which can reduce leakage risk between adjacent active pillars in a same row and leakage risk between adjacent active pillars in a same column, thus improving the performance of the semiconductor structure.

The embodiments or the implementation modes in this specification are described in a progressive manner, and each embodiment focuses on the differences from other embodiments. The same and similar parts between the embodiments can be referred to each other.

In the description of this specification, descriptions of the reference terms “an embodiment,” “some embodiments,” “illustrative embodiments,” “example,” “specific example,” or “some example,” etc. mean that specific features, structures, materials, or characteristics described in combination with the implementation modes or examples are included in at least one implementation mode or example of the disclosure.

In this specification, schematic expressions of the above terms do not necessarily refer to a same implementation mode or example. Furthermore, the specific features, structures, materials, or characteristics described may be combined in a suitable manner in any one or more implementation modes or examples.

Finally, it is to be noted that the above embodiments are only to illustrate, but not to limit the technical solutions of this disclosure. Although the disclosure has been described in detail with reference to the foregoing embodiments, it is to be understood by those of ordinary skill in the art that the technical solutions recited in the foregoing embodiments may be modified, or some or all of the technical features thereof may be equivalently replaced. The modifications or replacements do not depart the essence of the corresponding technical solution from the scope of the technical solution in the respective embodiments of the disclosure.

What is claimed is:

1. A semiconductor structure, comprising:
a base, wherein a first doped region is provided in the base; and
an active pillar group provided in the first doped region, wherein the active pillar group comprises four active pillars arranged in an array, wherein at least one of the active pillars is provided with a notch, wherein the notch faces at least one of a row centerline or a column centerline of the active pillar group.

2. The semiconductor structure according to claim 1, wherein each of the active pillars comprises a first pillar part and a second pillar part connected to the first pillar part; and the first pillar part and the second pillar part enclose the notch,
wherein among two active pillars in a same row, a second pillar part is disposed on a side of a first pillar part facing another first pillar part.

3. The semiconductor structure according to claim 2, wherein among two active pillars in a same column, the second pillar part is disposed at one end of the first pillar part away from another first pillar part, and notches provided in two active pillars located diagonally face each other.

4. The semiconductor structure according to claim 1, wherein multiple active pillar groups are provided, and the multiple active pillar groups are arranged in an array in the base.

5. The semiconductor structure according to claim 4, wherein in a direction perpendicular to the base, each of the active pillars comprises a channel region, and a source region and a drain region that are respectively arranged at either end of the channel region.

6. The semiconductor structure according to claim 5, wherein each of the active pillar groups further comprises a channel connecting region, each of the active pillars comprises a drain region, a channel region and a source region sequentially stacked from bottom to top in the direction perpendicular to the base; and
wherein in each of the active pillar groups, drain regions of the active pillars are connected to each other through the channel connecting region, wherein channel regions are connected to the channel connecting region, and the channel connecting region is connected to the base.

7. The semiconductor structure according to claim 6, further comprising: multiple first bit lines and multiple second bit lines, wherein the multiple first bit lines and the multiple second bit lines are alternately arranged in a first direction, and the first bit lines and the second bit lines extend in a second direction, wherein the first direction intersects the second direction; and
wherein each of the active pillar groups comprises a first surface and a second surface disposed oppositely in the first direction; wherein a first bit line is arranged on the first surface and connects the drain regions of the active pillars in a same column corresponding to the first surface; and a second bit line is arranged on the second surface and connects the drain regions of the active pillars in a same column corresponding to the second surface.

8. The semiconductor structure according to claim 7, further comprising: multiple first word lines and multiple second word lines, wherein the multiple first word lines and the multiple second word lines are alternately arranged in the second direction, and the first word lines and the second word lines extend in the first direction; and
wherein in the second direction, each of the active pillar groups comprises a third surface and a fourth surface disposed oppositely; wherein a first word line is arranged on the third surface and connects the channel regions of the active pillars in a same row corresponding to the third surface; and a second word lines is arranged on the fourth surface and connects the channel regions of the active pillars in a same row corresponding to the fourth surface.

9. The semiconductor structure according to claim 5, further comprising: multiple isolation structures, wherein each of the isolation structures is arranged in an area enclosed by the multiple active pillars in each of the active pillar groups, and bottom surfaces of the isolation structures are higher than top surfaces of the drain regions.

10. The semiconductor structure according to claim 9, wherein a capacitor is provided on each of the active pillars.

11. A manufacturing method of a semiconductor structure, comprising:
providing a base, wherein a first doped region is provided in the base; and
forming an active pillar group in the first doped region, wherein the active pillar group comprises four active pillars arranged in an array, wherein at least one of the active pillars is provided with a notch, wherein the notch faces at least one of a row centerline or a column centerline of the active pillar group.

12. The manufacturing method of a semiconductor structure according to claim 11, wherein forming an active pillar group in the first doped region comprises:
providing a mask comprising a rectangular first mask region and four second mask regions, wherein the four second mask regions are respectively arranged at corners of the first mask region, and each of the second mask regions wraps a corner of the first mask region;
etching the base that is not shielded by the mask by applying the mask, to form a pillar body in the first doped region, wherein the pillar body comprises a first pillar body and four second pillar bodies, wherein when taking a plane parallel to the base as a cross section, a cross-sectional shape of the first pillar body is rectangular, the four second pillar bodies are respectively arranged at corners of the first pillar body, and each of the second pillar bodies wraps a corner of the first pillar body;
removing a partial thickness of the first pillar body to form a filling hole in the first pillar body, wherein each of the second pillar bodies retained constitutes an intermediate pillar body;
forming an isolation structure in the filling hole, wherein a top surface of the isolation structure is flush with top surfaces of intermediate pillar bodies; and
performing ion implantation on a top surface of each of the intermediate pillar bodies to form a source region on a top surface of the intermediate pillar body, wherein the intermediate pillar body formed with the source region is regarded to be an active pillar, and four active pillars constitute an active pillar group.

13. The manufacturing method of a semiconductor structure according to claim 12, wherein multiple pillar bodies are provided, and the multiple pillar bodies are arranged in an array in the base.

14. The manufacturing method of a semiconductor structure according to claim 13, further comprising: after the operation of applying the mask and before removing a partial thickness of the first pillar body,
forming a first dielectric layer covering the pillar bodies on the base, wherein a top surface of the first dielectric layer is flush with top surfaces of the pillar bodies;
forming multiple first mask strips extending in a second direction on the first dielectric layer, wherein the multiple first mask strips are arranged at intervals in a first direction, and a first opening is formed between two adjacent first mask strips, wherein the first opening exposes the first dielectric layer between two adjacent columns of pillar bodies;
removing a partial thickness of the first dielectric layer exposed in the first opening to form a first groove, wherein the first groove exposes a first surface and a second surface of an active pillar group that are disposed oppositely in the first direction;
performing ion implantation on the first surface and the second surface, so as to form second doped regions in the second pillar bodies, wherein a type of doping ions in the second doped regions is different from a type of doping ions in the first doped region, and the second doped regions are configured to form drain regions;
removing the first mask strips;
forming a second dielectric layer in the first groove, wherein a top surface of the second dielectric layer is lower than the top surfaces of the pillar bodies;
forming a third dielectric layer on the second dielectric layer, wherein a top surface of the third dielectric layer is flush with the top surfaces of the pillar bodies;
forming second mask strips extending in the first direction on the third dielectric layer, wherein multiple second mask strips are arranged at intervals in the second direction, and a second opening is formed between two adjacent second mask strips, wherein the second opening exposes the third dielectric layer between two adjacent rows of pillar bodies;
removing the third dielectric layer exposed in the second opening to form a second groove, wherein the second groove exposes a third surface and a fourth surface of the active pillar group that are disposed oppositely in the second direction; and
performing ion implantation on the third surface and the fourth surface to form third doped regions in the second pillar bodies, wherein a type of doping ions in the third doped regions is different from the type of doping ions in the second doped regions and the same as the type of doping ions in the first doped region, and the third doped regions are configured to form channel regions.

15. The manufacturing method of a semiconductor structure according to claim 14, further comprising: after performing ion implantation on exposed opposite surfaces of the second pillar bodies adjacent in the first direction and before removing the first mask strips,
forming a first bit line and a second bit line in the first groove, wherein the first bit line and the second bit line both extend in the second direction, the first bit line connects the drain regions of the pillar body corresponding to the first surface exposed in the first groove, and the second bit line connects the drain regions of the pillar body corresponding to the second surface exposed in the first groove.

16. The manufacturing method of a semiconductor structure according to claim 14, further comprising: after performing ion implantation on exposed opposite surfaces of the second pillar bodies adjacent in the second direction,
forming a first word line and a second word line in the second groove, wherein the first word line and the second word line both extend in the first direction, and the first word line connects the channel regions of the pillar body corresponding to the third surface exposed in the second groove, and the second word line connects the channel regions of the pillar body corresponding to the fourth surface exposed in the second groove; and
removing the second mask strips.

17. The manufacturing method ofa semiconductor structure according to claim 11, wherein providing the base comprises:
providing a substrate;
forming a first protective layer and a mask layer with a mask pattern on the substrate; and
performing ion doping on the substrate to form a first doped region in the substrate, wherein the substrate having the first doped region constitutes the base.

18. The manufacturing method of a semiconductor structure according to claim 14, comprising: after removing a partial thickness of the first dielectric layer exposed in the first opening and before performing ion implantation on exposed opposite surfaces of the second pillar bodies adjacent in the first direction,
forming a second protective layer on the second pillar bodies exposed in the first groove, wherein the second protective layer is configured to protect the second pillar bodies.

19. The manufacturing method of a semiconductor structure according to claim 18, further comprising: after removing the third dielectric layer exposed in the second opening to form a second groove and before performing ion implantation on exposed opposite surfaces of the second pillar bodies in the second direction,
forming a third protective layer on the second pillar bodies exposed in the second groove, wherein the third protective layer is configured to protect the second pillar bodies.

20. The manufacturing method of a semiconductor structure according to claim 19, further comprising: after performing ion implantation on the third surface and the fourth surface and before forming the first word line and the second word line in the second groove,
forming a gate oxide layer on the channel regions.
